(19) United States
(12) Patent Application Publication
(10) Pub. No.: US 2026/0246271 A1
(43) Pub. Date: Aug. 20, 2026

(54) POWER SUPPLY SYSTEM FOR RAILWAY VEHICLES

(71) Applicant: Mitsubishi Electric Corporation, Chiyoda-ku, Tokyo (JP)

(72) Inventors: Yoichi FUKUDA, Tokyo (JP); Takashi NAGATA, Tokyo (JP); Osamu ARAI, Tokyo (JP); Kouhei KARASAWA, Tokyo (JP); Akihide TOMOMATSU, Tokyo (JP)

(73) Assignee: Mitsubishi Electric Corporation, Chiyoda-ku, Tokyo (JP)

(21) Appl. No.: 18/876,848

(22) PCT Filed: Jun. 28, 2022
(86) PCT No.: PCT/JP2022/025828

§ 371 Date: Dec. 19, 2024

(51) Int. Cl. H02J 3/0014; B61D 27/00; G01R 19/165; H02J 3/14; H02J 105/10; H02J 105/40; H02J 105/50; H02J 105/52

(52) U.S. Cl. CPC H02J 3/0014; B61D 27/0018; G01R 19/16595; H02J 3/14; H02J 2105/10; H02J 2105/40; H02J 2105/51; H02J 2105/52

(57) ABSTRACT

A power supply system for railway vehicle includes a plurality of power supply apparatuses installed on a vehicle of a train to supply alternating-current power to a plurality of air conditioning devices within the train in parallel via output contactors and a common bus. The air conditioning devices of the vehicles each generate a step calorie information item that refers to information on power requirement for an air-conditioning target space. A collection device gathers the step calorie information item generated by each of the air conditioning devices of the vehicles and computes total step calorie information for all the vehicles by summing up the step calorie information items. Each of the power supply apparatuses determines whether to suspend the power supply to the air conditioning devices on the basis of the total step calorie information for all the vehicles that is transmitted from the collection device.

### Field

The present disclosure relates to a power supply system for railway vehicles that is installed on train vehicles to supply power to onboard loads, such as air conditioning devices and lighting equipment, via output contactors and a common bus.

### BACKGROUND

Patent Literature 1 below discloses a power supply system for railway vehicles that is aimed at reducing power loss. Specifically, in the power supply system described in Patent Literature 1, two power supply apparatuses installed on train vehicles each mutually monitor onboard loads of an own vehicle and another vehicle for load power. When the load power of both onboard loads fall below a specified value, a power supply apparatus that supplies power to one of the onboard loads stops supplying power. In other words, the technique described in Patent Literature 1 discloses suspension control that uses information on the load power of each onboard load to determine whether or not to suspend the power supply to the onboard load.

### CITATION LIST

### Patent Literature

Patent Literature 1: Japanese Patent Application Laid-open No. 2010-166730

### SUMMARY OF INVENTION

### Problem to Be Solved by the Invention

An air conditioning device is one of loads that has a significant power requirement among onboard loads. Output power of the air conditioning device significant fluctuates due to temperature and a vehicle occupancy rate. Furthermore, in a power supply apparatus for railway vehicles that supplies power via an output contactor, the suspension of the power supply to an onboard load is performed by the use of the output contactor. Therefore, when the technique described in Patent Literature 1 is applied to power supply apparatuses with this configuration, some of the power supply apparatuses may frequently alternate between the suspension and the operation in association with fluctuations in load power. In that case, there is a problem in that contacts of the output contactors connected to those power supply apparatuses wear at faster rates, lifespans of the output contactors decrease.

The present disclosure has been made in view of the above, and an object of the present disclosure is to obtain a power supply system for railway vehicles that enables efficient power supply to onboard loads while mitigating the reduction of each output contactor's lifespan.

### Means to Solve the Problem

In order to solve the above-stated problem and achieve the object, a power supply system for railway vehicle according to the present disclosure includes a plurality of power supply apparatuses installed on a vehicle of a train to supply alternating-current power to a plurality of air conditioning devices within the train in parallel via output contactors and a common bus. Each of the air conditioning devices generates a first power information item that indicates information on power requirement for an air-conditioning target space. A collection device gathers the first power information item generated by each of the air conditioning devices and computes a second power information item that is the sum of the first power information items. Each of the power supply apparatuses determines whether or not to suspend the power supply to the air conditioning devices on the basis of the second power information item transmitted from the collection device.

### Effects of the Invention

according to the present disclosure has an effect of efficiently supplying the power to onboard loads while mitigating reduction of each output contactor's lifespan.

### BRIEF DESCRIPTION OF DRAWINGS

FIG. 1 is a diagram illustrating a basic configuration of a power supply apparatus for railway vehicle according to a first embodiment and a relation of the power supply apparatus with other constituent elements.

FIG. 2 is a diagram illustrating a configuration of a power supply system for railway vehicles according to the first embodiment.

FIG. 3 is a system configuration diagram used to describe how suspended operation control according to the first embodiment works.

FIG. 4 is a flowchart used to describe how the suspended operation control according to the first embodiment works.

FIG. 5 is a diagram used to describe an effect of the suspended operation control according to the first embodiment.

FIG. 6 is a block diagram illustrating an example of a hardware configuration that implements functions of a control unit according to the first embodiment.

FIG. 7 is a block diagram illustrating another example of the hardware configuration that implements the functions of the control unit according to the first embodiment.

FIG. 8 is a flowchart used to describe how suspended operation control according to a second embodiment works.

### DESCRIPTION OF EMBODIMENTS

With reference to the accompanying drawings, a detailed description is hereinafter provided of power supply systems for railway vehicles according to embodiments of the present disclosure.

### First Embodiment

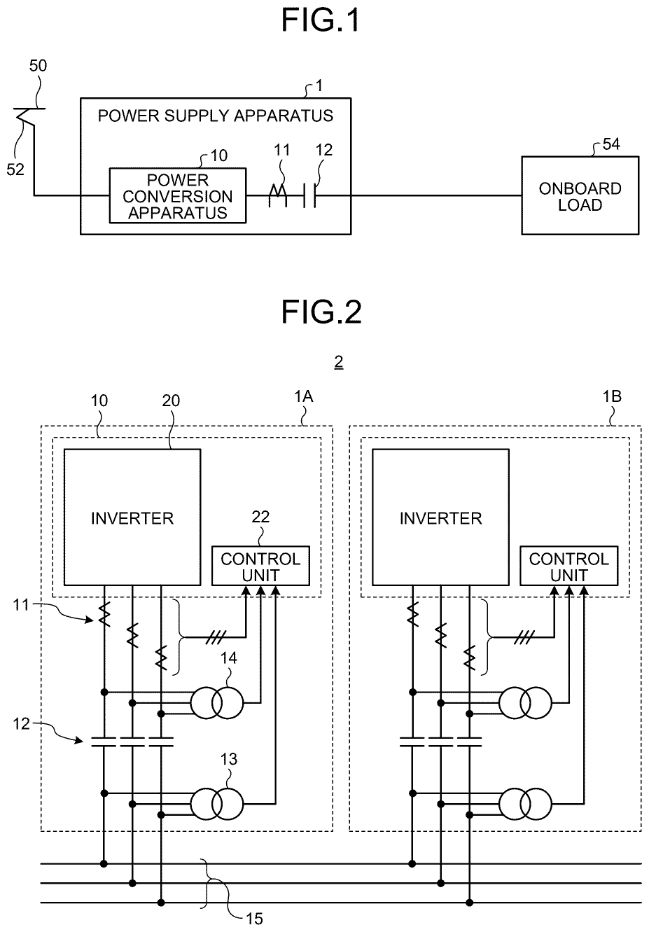

FIG. 1 is a diagram illustrating a basic configuration of a power supply apparatus for railway vehicle (hereinafter simply referred to as the “power supply apparatus”) according to a first embodiment and a relation of the power supply apparatus with other constituent elements. FIG. 1 illustrates main constituent elements of the power supply apparatus 1 according to the first embodiment. The power supply apparatus 1 is installed on a vehicle within a train. As illustrated in FIG. 1, the power supply apparatus 1 includes a power conversion apparatus 10, a current detector 11, and an output contactor 12. The power conversion apparatus 10 receives direct-current power supplied from an overhead line 50 via a collector 52, converts the received direct-current power into alternating-current power, and supplies the alternating-current power to an onboard load 54. The onboard load 54 is any load other than a traction motor among loads installed on train vehicles. Examples of the onboard load 54 include an air conditioning device, interior lighting equipment, a door opening and shutting device, safety equipment, and a control power supply, among others.

The current detector 11 is disposed between the power conversion apparatus 10 and the output contactor 12. The current detector 11 detects current flowing in and out of the power conversion apparatus 10. The power is supplied to the onboard load 54 via the output contactor 12. Contacts of the output contactor 12 are closed when supplying the power to the onboard load 54. The contacts of the output contactor 12 are opened when temporarily suspending the power supply to the onboard load 54. The opening and closing of the contacts of the output contactor 12 are controlled by the power conversion apparatus 10.

In FIG. 1, the power supplied from the overhead line 50 is the direct-current power, indicating that the overhead line 50 is a direct-current overhead line; however, the overhead line 50 may be an alternating-current overhead line. When the overhead line 50 is the alternating-current overhead line, a traction transformer is inserted between the collector 52 and the power conversion apparatus 10. The power conversion apparatus 10 converts alternating-current power supplied from the traction transformer into direct-current power and converts the converted direct-current power into alternating-current power for the onboard load 54.

FIG. 2 is a diagram illustrating a configuration of a power supply system for railway vehicles (hereinafter simply referred to as the “power supply system”) according to the first embodiment. In FIG. 2, the power supply system 2 includes two power supply apparatuses 1A and 1B to ensure redundancy. Each of the power supply apparatuses 1A and 1B is set to a capacity higher than actually required to ensure that even if one of the power supply apparatuses 1A and 1B fails, the remaining one alone can supply the power to all onboard loads 54 or major onboard loads 54. The number of power supply apparatuses is determined on the basis of how many vehicles the train is composed of. When a train is composed of many vehicles, three or more power supply apparatuses may be installed.

The power supply apparatuses 1A and 1B are connected to a three-phase common bus 15 wired within and between the vehicles. Although not illustrated, the plural onboard loads 54 are connected to the common bus 15 in FIG. 2. In other words, in the power supply system 2, the power supply apparatuses 1A and 1B are configured to supply the alternating-current power to the plural onboard loads 54 within the train in parallel via the common bus 15.

Next, a description is provided of how each of the power supply apparatuses 1A and 1B is configured and functions. The power supply apparatuses 1A and 1B have the same configuration and functions. The description is provided, referring to the power supply apparatus 1A below. When not distinguished individually in the following description, each the power supply apparatuses 1A and 1B is referred to as “the power supply apparatus 1” without subscripts.

The power supply apparatus 1 includes voltage detectors 13 and 14 in addition to the current detector 11 and the output contactor 12 described earlier. The power conversion apparatus 10 includes an inverter 20 and a control unit 22. The inverter 20 is a power conversion unit that converts the direct-current or alternating-current power supplied from the overhead line 50 into the three-phase alternating-current power for the onboard loads 54. The voltage detector 13 detects voltage of the common bus 15, namely the three-phase alternating-current voltage applied to the common bus 15. The voltage detector 14 detects three-phase alternating-current voltage output by the inverter 20 by detecting the voltage between the inverter 20 and the output contactor 12. The detection values of the voltage detectors 13 and 14, along with the detection value of the current detector 11, are input to the control unit 22. On the basis of the detection values from the voltage detectors 13 and 14 and the detection value from the current detector 11, the control unit 22 controls the operation of the inverter 20. Furthermore, the control unit 22 controls the opening and closing of the output contactor 12.

The plural power supply apparatuses 1 perform synchronized parallel operation for the plural onboard loads 54 within the train. The synchronized parallel operation is an operational method where the plural power supply apparatuses 1 each output the three-phase alternating-current voltage to the common bus 15, with their output voltages matched in amplitude and phase. To perform this synchronized parallel operation, each power supply apparatus 1 is equipped with the voltage detectors 13 and 14. In the example of FIG. 2, when both the power supply apparatuses 1A and 1B output the three-phase alternating-current voltage, the power supply apparatuses 1A and 1B equally share a load power demand within the train. Therefore, in this case, each of the power supply apparatuses 1A and 1B is responsible for half of total load current. The current detector 11 of each of the power supply apparatuses 1A and 1B detects this half of the load current.

Next, using an example where the onboard loads 54 are air conditioning devices, a description is provided of a problem involved when the plural power supply apparatuses 1 in synchronized parallel operation supply the power to the air conditioning devices. In the first place, the capacity of each power supply apparatus 1 is set with consideration given to ensuring that each air conditioning device, which is the major onboard load 54, can operate continuously at its maximum output point. However, in actual operation, the air conditioning device experiences fluctuations in output due to temperature, weather, and a vehicle occupancy rate, and on average, the air conditioning device operates more often at lower outputs.

Operating efficiency of each power supply apparatus 1 deteriorates as a load factor relative to the rated capacity of the power supply apparatus 1 decreases. This is because a proportion of iron losses from a reactor and a transformer in the power supply apparatus 1 to power consumption of the power supply apparatus 1 increases.

Accordingly, in the first embodiment, to increase the operating efficiency of the power supply apparatus 1, control is performed such that when the load factor within the train is low, the operation of one of the power supply apparatuses 1 is suspended, and the remaining power supply apparatus 1 increases its output to operate at a point where its efficiency is higher for the load factor. In other words, in the first embodiment, coordinated operation control is performed with the air conditioning devices, which are the major loads of the power supply apparatuses 1. The operation implemented by this control is hereinafter referred to as the “suspended operation”. The control that implements the suspended operation is referred to as the “suspended operation control”.

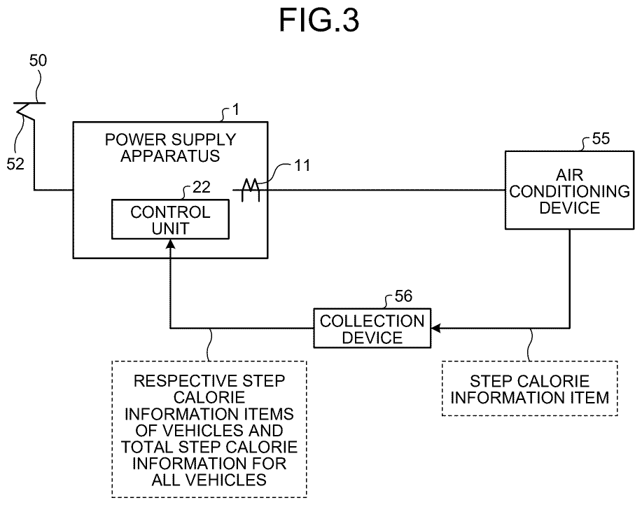

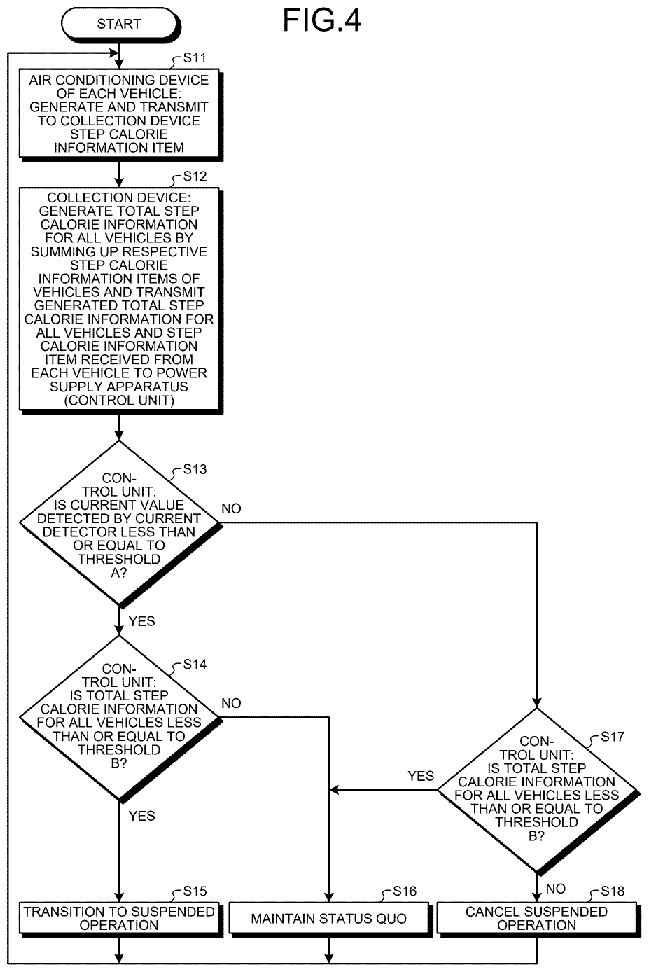

Next, with reference to FIGS. 3 and 4, a description is provided of operation during the suspended operation control according to the first embodiment. FIG. 3 is a system configuration diagram used to describe how the suspended operation control according to the first embodiment works. FIG. 4 is a flowchart used to describe how the suspended operation control according to the first embodiment works. The power supply system 2 according to the first embodiment includes a collection device 56 in addition to the constituent elements described earlier.

As illustrated in the system configuration diagram of FIG. 3, the power supply system 2 according to the first embodiment includes, in addition to the previously described constituent elements, the collection device 56. The collection device 56 may be any device as long as the device can receive information of each air conditioning device 55 and transmit the information held by each air conditioning device 55 to the control unit 22 of the power supply apparatus 1. Recent trains are each equipped with a train information management system that manages train information. A central device of the train information management system has a function of ascertaining operating states of the onboard loads 54. Therefore, the central device of the train information management system can be used as the collection device 56.

In FIG. 4, the air conditioning device 55 of each of the vehicles generates and transmits to the collection device 56 a step calorie information item (step S11). The step calorie information item refers to information on power requirement for an air-conditioning target space by the air conditioning device 55. The air conditioning device 55 constantly predicts power consumption for air-conditioning the air-conditioning target space through computation. The air conditioning device 55 computes the step calorie information item on the basis of a difference between a preset vehicle interior temperature and vehicle interior temperature, the occupancy rate of the vehicle, and other information.

The collection device 56 generates total step calorie information for all the vehicles by summing up the step calorie information items of the vehicles. Furthermore, the collection device 56 transmits the generated total step calorie information for all the vehicles and the step calorie information item(s) received from each vehicle to the control unit 22 of the power supply apparatus 1 (step S12).

The control unit 22 determines whether or not the current value detected by the current detector 11 is less than or equal to threshold A, which is a first threshold (step S13). If the current value detected by the current detector 11 is less than or equal to threshold A (step S13, Yes), the control unit 22 determines whether or not the total step calorie information for all the vehicles is less than or equal to threshold B, which is a second threshold (step S14). If the total step calorie information for all the vehicles is less than or equal to threshold B (step S14, Yes), the control unit 22 determines that the air conditioning devices 55 within the train are in a light-load operating state and transitions to the suspended operation (step S15). The operations are repeated thereafter, starting from step S11.

A return is made to step S14. If the total step calorie information for all the vehicles is above threshold B (step S14, No), the control unit 22 determines that there is no significant change in the load state of the air conditioning devices 55 and maintains the present status (step S16). In other words, when the suspended operation control is in progress for the air conditioning devices 55, the suspended operation control is maintained. When the normal synchronized parallel operation is in progress for the air conditioning devices 55 instead of the suspended operation control, the synchronized parallel operation is maintained. The operations are repeated thereafter, starting from step S11.

A return is made to step S13. If the current value detected by the current detector 11 is above threshold A (step S13, No), the control unit 22 determines whether or not the total step calorie information for all the vehicles is less than or equal to threshold B (step S17). If the total step calorie information for all the vehicles is above threshold B (step S17, No), the control unit 22 determines that the air conditioning devices 55 within the train are in or about to transition to a high-load operating state and cancels the suspended operation (step S18). In other words, when the suspended operation control is in progress for the air conditioning devices 55, the suspended operation is canceled, and the synchronized parallel operation is performed. When the synchronized parallel operation is in progress for the air conditioning devices 55, the synchronized parallel operation is maintained. The operations are repeated thereafter, starting from step S11.

A return is made to step S17. If the total step calorie information for all the vehicles is less than or equal to threshold B (step S17, Yes), the control unit 22 maintains the present status (step S16). In other words, when the suspended operation control is in progress for the air conditioning devices 55, the suspended operation control is maintained. When the synchronized parallel operation is in progress for the air conditioning devices 55 and the suspended operation control is not performed, the synchronized parallel operation is maintained. The operations are repeated thereafter, starting from step S11.

It is to be noted that the processing flow in FIG. 4 is not performed by every power supply apparatus 1 within the train, but by a specified power supply apparatus. At least one power supply apparatus is selected from the power supply apparatuses 1 within the train as the specified power supply apparatus. The specified power supply apparatus is changed daily or in accordance with a preset rotation. For example, in the configuration of FIG. 2, when the power supply apparatus 1A is the specified power supply apparatus, the power supply apparatus 1A alone performs the processing flow in FIG. 4, and the power supply apparatus 1B does not perform the processing flow in FIG. 4. When the power supply apparatus 1A is in suspended operation, the power supply apparatus 1B alone covers the power demand of the onboard loads 54. In cases where the specified power supply apparatus is changed daily, the power supply apparatus 1B becomes the specified power supply apparatus on a subsequent day of operation. This allows for equalized operation of the output contactors 12 among the plural power supply apparatuses 1, it is possible to prevent the contacts of some or specific output contactors 12 from wearing out.

When a train includes three power supply apparatuses 1, one or two of the power supply apparatuses are set as the specified power supply apparatuses, and the remaining power supply apparatus 1 covers the power demand of the onboard loads 54 in a low-load state. Even when there are four or more power supply apparatuses 1, the specified power supply apparatuses can be determined in a similar manner.

While the information output from each air conditioning device 55 is the step calorie information item in the above description, this example is not limiting. The information output from each air conditioning device 55 does not need to be the step calorie information item and may be any information from which information on power requirement for the air-conditioning target space by the air conditioning device 55 can be ascertained. Therefore, in the following description, the information corresponding to the step calorie information item output from each air conditioning device 55 may be described as the “first power information item”, and information corresponding to the total step calorie information for all the vehicles, which is the sum of the step calorie information items of the vehicles, may be described as the “second power information item”.

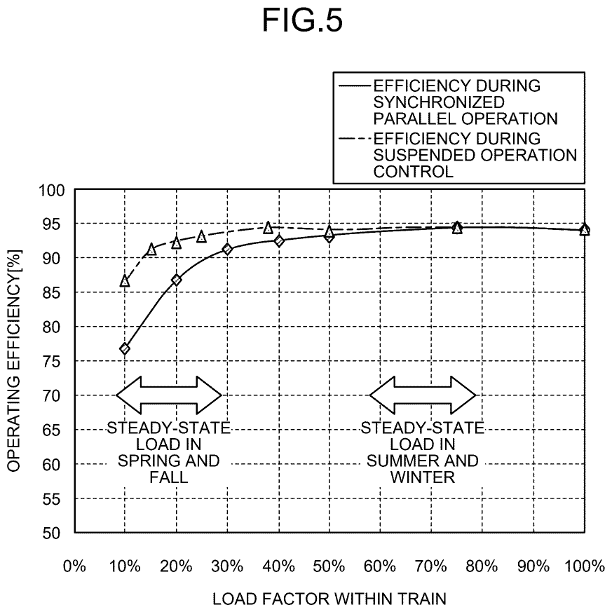

FIG. 5 is a diagram used to describe an effect of the suspended operation control according to the first embodiment. In FIG. 5, a horizontal axis represents the load factor within the train, and a vertical axis represents the operating efficiency of one power supply apparatus 1. The load factor within the train represents a ratio, in percentage, of power requirements of the air conditioning devices 55 to power requirements of the onboard loads 54 within the train. A solid curve connecting diamond-shaped plots represents the operating efficiency when the two power supply apparatuses are in synchronized parallel operation. A dashed curve connecting triangular plots represents the operating efficiency during the suspended operation control, that is to say, when one of the two power supply apparatuses is suspended.

As illustrated in FIG. 5, a steady-state load, which is the typical load factor within the train for the air conditioning devices 55, ranges from just under 60% to just under 80% in summer and winter but from just under 10% to just under 30% in spring and fall. Therefore, with the synchronized parallel operation, the operating efficiency can be kept high in summer and winter but decreases in spring and fall. With the suspended operation control, by contrast, suspending the operation of one of the power supply apparatuses 1 allows the remaining one of the power supply apparatuses 1 to operate at a point where the efficiency is higher for the load factor. This control can keep the operating efficiency high in summer and winter and mitigate the reduction of the operating efficiency in spring and fall.

As described above, the power supply system according to the first embodiment includes the collection device that gathers the first power information item generated by each air conditioning device within the train and computes the second power information item, which is the sum of the first power information items. The first power information item indicates the information on power requirement for the air-conditioning target space by the air conditioning device and is generated by each air conditioning device. Each power supply apparatus determines, on the basis of the second power information item transmitted from the collection device, whether or not to suspend the power supply to the air conditioning devices, specifically whether or not to perform the suspended operation control. The second power information item refers to information on power requirement for the air conditioning devices across the entire train. Therefore, when the suspended operation control is performed based on the use of the second power information item, it is possible to avoid frequent alternation between the suspension and the operation in some of the power supply apparatuses. As a result, the reduction of each connected output contactor's lifespan in those power supply apparatuses can be mitigated. Furthermore, with the suspended operation control where the operation of those power supply apparatuses is suspended, the power supply apparatus or apparatuses that are not suspended can operate at a point where the efficiency is higher for the load factor. This enables efficient power supply to the onboard loads.

When the above-described suspended operation control is performed, it is preferable to set up the specified power supply apparatus(es), and the specified power supply apparatus or apparatuses are preferably changed daily or in accordance with the preset rotation. Setting the specified power supply apparatus(es) can prevent lifespans of some of the output contactors from reducing extremely.

In the suspended operation control according to the first embodiment, the specified power supply apparatus among the power supply apparatuses transitions to the suspended operation to suspend the power supply to the air conditioning devices when the current value detected by the current detector is less than or equal to the first threshold and the second power information item is less than or equal to the second threshold. A determination process using the two thresholds enables a simple and reliable transition to the suspended operation.

In the suspended operation control according to the first embodiment, the specified power supply apparatus among the power supply apparatuses cancels the suspended operation when the current value detected by the current detector is above the first threshold and the second power information item is above the second threshold. The determination process using the two thresholds enables a simple and reliable cancellation of the suspended operation.

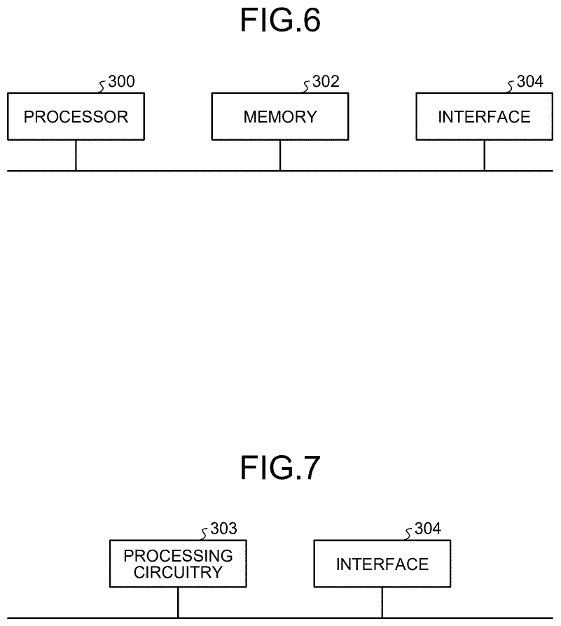

Next, with reference to FIGS. 6 and 7, a description is provided of a hardware configuration that implements the functions of the above-described control unit 22. FIG. 6 is a block diagram illustrating an example of the hardware configuration that implements the functions of the control unit 22 according to the first embodiment. FIG. 7 is a block diagram illustrating another example of the hardware configuration that implements the functions of the control unit 22 according to the first embodiment.

To implement part or all of the functions of the control unit 22 according to the first embodiment, as illustrated in FIG. 6, the configuration can include a processor 300 that performs computations, a memory 302 that stores programs to be read by the processor 300, and an interface 304 across which signals are input and output.

The processor 300 is an example of an operation means. The processor 300 may be an operation means referred to as a microprocessor, a microcomputer, a central processing unit (CPU), or a digital signal processor (DSP). The memory 302 can be exemplified by a magnetic disk, a flexible disk, an optical disk, a compact disk, a mini disk, a digital versatile disc (DVD), or a nonvolatile or volatile semiconductor memory, such as a random-access memory (RAM), a read-only memory (ROM), a flash memory, an erasable programmable ROM (EPROM), or an electrically EPROM (EEPROM) (registered trademark).

The memory 302 stores the programs that implement the functions of the control unit 22 according to the first embodiment. The processor 300 transmits and receives necessary information via the interface 304 and executes the programs stored in the memory 302. By referring to a table stored in the memory 302, the processor 300 is capable of performing the above-described operations. Operation results of the processor 300 can be stored in the memory 302.

Processing circuitry 303 illustrated in FIG. 7 can also be used to implement part of the functions of the control unit 22 according to the first embodiment. The processing circuitry 303 corresponds to a single circuit, a composite circuit, an application-specific integrated circuit (ASIC), a field-programmable gate array (FPGA), or a combination of these. Information to be input to the processing circuitry 303 and information to be output from the processing circuitry 303 can be obtained via the interface 304.

Some of the operations of the control unit 22 may be performed by the processing circuitry 303, while the other operations, which are not performed by the processing circuitry 303, may be performed using the processor 300 and the memory 302.

### Second Embodiment

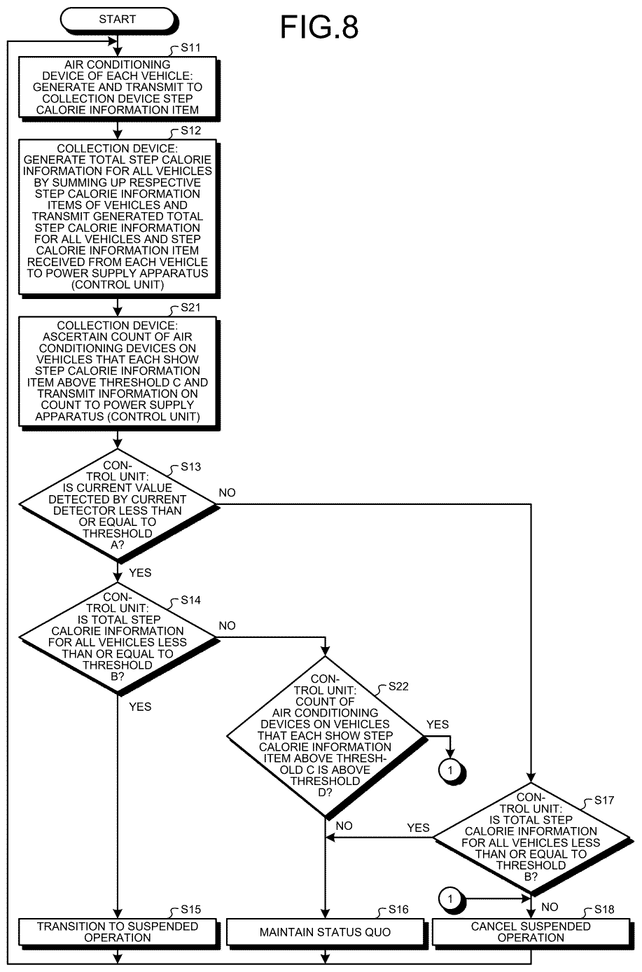

In a second embodiment, a description is provided of a modification of the process for canceling the suspended operation in the suspended operation control according to the first embodiment. FIG. 8 is a flowchart used to describe how suspended operation control according to the second embodiment works. In FIG. 8, parts identical or equivalent to the operations in the flowchart of FIG. 4 have the same reference characters. The following description focuses on operations added in FIG. 8. The operations of the second embodiment are performed by a power supply system 2 with a configuration identical or equivalent to that of the first embodiment. As in the first embodiment, the processing flow in FIG. 8 is performed by a specified power supply apparatus.

In the operation of step S11, the collection device 56 receives step calorie information items. Furthermore, in the operation of step S12, the collection device 56 transmits total step calorie information generated for all vehicles and the step calorie information item(s) received from each of the vehicles to the control unit 22.

Furthermore, the collection device 56 ascertains a count of air conditioning devices 55 having the step calorie information items for the vehicles above threshold C, which is a third threshold, and transmits information on the count to the control unit 22 of the power supply apparatus 1 (step S21). Threshold C is a smaller value than threshold B that is the second threshold.

At step S13, the control unit 22 determines whether or not a current value detected by the current detector 11 is less than or equal to threshold A. At step S14, the control unit 22 determines whether or not the total step calorie information for all the vehicles is less than or equal to threshold B.

If the total step calorie information for all the vehicles is above threshold B (step S14, No), the control unit 22 determines whether or not the count of air conditioning devices 55 having the step calorie information items for the vehicles above threshold C is above threshold D, which is a fourth threshold (step S22). If the count of air conditioning devices 55 having the step calorie information items for the vehicles above threshold C is less than or equal to threshold D (step S22, No), the control unit 22 determines that there is no significant change in the load state of the air conditioning devices 55 and maintains the present status (step S16). The operations are repeated thereafter, starting from step S11.

A return is made to step S22. If the count of air conditioning devices 55 having the step calorie information items for the vehicles above threshold C is above threshold D (step S22, Yes), the control unit 22 determines that the air conditioning devices 55 within a train are in or about to transition to the high-load operating state and cancels the suspended operation (step S18). The operations are repeated thereafter, starting from step S11.

As described above, in the suspended operation control according to the second embodiment, the collection device determines whether or not each of the first power information items is above the third threshold, which is smaller than the second threshold, and also ascertains and transmits to the power supply apparatus the count of air conditioning devices that each show the first power information item above the third threshold. The specified power supply apparatus among the power supply apparatuses cancels the suspended operation when the current value detected by the current detector is above the first threshold and the second power information item is above the second threshold or when the current value detected by the current detector is above the first threshold and the count of air conditioning devices that each have the first power information item above the third threshold is above the fourth threshold. Consequently, a simple and reliable transition to the suspended operation is enabled as in the first embodiment. A determination process that includes the two more thresholds can further enhance the reliability of the process for canceling the suspended operation compared to the first embodiment.

The above configurations illustrated in the embodiments are illustrative, can be combined with other techniques that are publicly known, and can be partly omitted or changed without departing from the gist.

### REFERENCE SIGNS LIST

1, 1A, 1B power supply apparatus; 2 power supply system; 10 power conversion apparatus; 11 current detector; 12 output contactor; 13, 14 voltage detector; 15 common bus; 20 inverter; 22 control unit; 50 overhead line; 5 collector; 54 onboard load; 55 air conditioning device; 56 collection device; 300 processor; 302 memory; 303 processing circuitry; 304 interface.

1. A power supply system for railway vehicle comprising a plurality of power supply apparatuses installed on a vehicle of a train to supply alternating-current power to a plurality of air conditioning devices within the train in parallel via output contactors and a common bus, wherein
each of the air conditioning devices generates a first power information item that indicates information on power requirement for an air-conditioning target space,
the power supply system comprises a collection device to gather the first power information item generated by each of the air conditioning devices and compute a second power information item that is a sum of the first power information items, and
each of the power supply apparatuses determines whether or not to suspend the power supply to the air conditioning devices on a basis of a second power information item transmitted from the collection device.

2. The power supply system for railway vehicle according to claim 1, wherein
each of the power supply apparatuses includes the output contactor,
a current detector is included between each of the power supply apparatuses and a corresponding one of the output contactors, and
a specified power supply apparatus among the power supply apparatuses transitions to suspended operation and suspends the power supply to the air conditioning devices when a current value detected by the current detector is less than or equal to a first threshold and the second power information item is less than or equal to a second threshold.

3. The power supply system for railway vehicle according to claim 2, wherein
each of the power supply apparatuses includes the output contactor,
a current detector is included between each of the power supply apparatuses and a corresponding one of the output contactors, and
a specified power supply apparatus among the power supply apparatuses cancels the suspended operation when a current value detected by the current detector is above a first threshold and the second power information item is above a second threshold.

4. The power supply system for railway vehicle according to claim 2, wherein
each of the power supply apparatuses includes the output contactor,
a current detector is included between each of the power supply apparatuses and a corresponding one of the output contactors,
the collection device determines whether or not the first power information item is above a third threshold that is smaller than the second threshold and also ascertains and transmits to the power supply apparatuses a count of air conditioning devices that each have the first power information item above the third threshold, and
a specified power supply apparatus among the power supply apparatuses cancels the suspended operation when a current value detected by the current detector is above a first threshold and the second power information item is above a second threshold or when a current value detected by the current detector is above a first threshold and a count of air conditioning devices each having the first power information item above the third threshold is above a fourth threshold.

5. The power supply system for railway vehicle according to claim 2, wherein
the specified power supply apparatus is changed daily or in accordance with a preset rotation.

6. The power supply system for railway vehicle according to claim 3, wherein
the specified power supply apparatus is changed daily or in accordance with a preset rotation.

7. The power supply system for railway vehicle according to claim 4, wherein
the specified power supply apparatus is changed daily or in accordance with a preset rotation.
